(19) United States
(12) Patent Application Publication
(10) Pub. No.: US 2008/0261384 A1
(43) Pub. Date: Oct. 23, 2008

(54) METHOD OF REMOVING PHOTORESIST LAYER AND METHOD OF FABRICATING SEMICONDUCTOR DEVICE USING THE SAME

(75) Inventors: Zhi-Qiang Sun, Singapore (SG); Xi PEI, Singapore (SG); Tien-Cheng Lan, Taipei County (TW); Yu-Jou Chen, Tainan City (TW); Guo-Fu Zhou, Singapore (SG); Kai-Ping Huang, Tainan County (TW); Hong-Siek Gan, Muar Johor (MY); Jian-Peng Yan, Singapore (SG); Kai YANG, Singapore (SG); Sheng ZHANG, Singapore (SG)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/736,904

(22) Filed: Apr. 18, 2007

(51) Int. Cl. H01L 21/425; G03C 5/00

(52) U.S. Cl. 438/514; 430/329; 257/E21.473

(57) ABSTRACT

A method of removing a photoresist layer is provided. An ion implantation process has been performed on the photoresist layer to transform a surface of the photoresist layer to a crust and a soft photoresist layer remains within the crust. The method includes performing a first removing step to remove the crust, such that the soft photoresist layer is exposed. Thereafter, a second removing step is performed to remove the soft photoresist layer. The first and the second removing steps are performed in difference chambers, and a temperature for performing the first removing step is lower than that for performing the second removing step and lower than a gasification temperature of a solvent in the soft photoresist layer.

### BACKGROUND OF THE INVENTION

1. Field of the Invention

The present invention relates to a method of fabricating an integrated circuit, and more particularly to a method of removing a photoresist layer and a method of fabricating a semiconductor device using the same.

2. Description of Related Art

In a process of manufacturing semiconductors, a great number of integrated circuits are frequently formed on substrates. A plurality of electronic devices such as transistors, diodes, capacitors, resistors and the like is often included in the integrated circuits. Fabrication of the electronic devices usually involves depositing, removing, and implanting ions at certain locations which can be facilitated by a photolithography process.

The photolithography process includes depositing a layer of photoresist material on a substrate at first. Then, patterns on a photomask are transferred to the photoresist material layer after being exposed to radiation passing through the photomask. Next, a portion of the photoresist material layer is removed by a developer, such that photoresist patterns are formed. The typical photoresist material is composed of photosensitive polymers, resin, and solvents. With a positive photoresist material, the exposed resist undergoing pyrolysis is removed by the developer. Conversely, with a negative photoresist material, the unexposed resist experiencing no cross-linking effect is removed by the developer. After the photoresist patterns are formed, a subsequent process such as an etching of a dielectric layer, the etching of a metal layer, or the ion implantation process is then be performed with use of the photoresist patterns as masks. The photoresist layer must be removed after the subsequent process is completed, and a dry etching method or a wet etching method may be adopted to remove the photoresist layer. In most cases, oxygen plasma may be employed in the dry etching method to oxidize the photoresist layer, while an organic solution or any other acid solution may be utilized in the wet etching method to remove the same. Afterwards, a cleaning process is carried out to remove the residual photoresist layer on a surface of the substrate or the impurities.

However, referring to FIG. 1A, when a photoresist layer 10 on a substrate 8 is used as a mask in an ion implantation process, the photoresist layer 10 is extremely hard to strip after said ion implantation process is implemented. The difficulty of removing the photoresist layer 10 may lie in that ions penetrate into the photoresist layer 10 during the ion implantation process, and thereby chemical bonds occurring in a surface of the photoresist layer 10 become cross-linked, causing the surface of the photoresist layer 10 to be transformed into a difficult-to-remove crust 14. A solvent-containing soft photoresist layer 12 is covered by the crust 14. Due to said cross-linking effect, the surface material having an H—C—H bond may be changed to a C—C—C bond, or the following reaction is then induced,

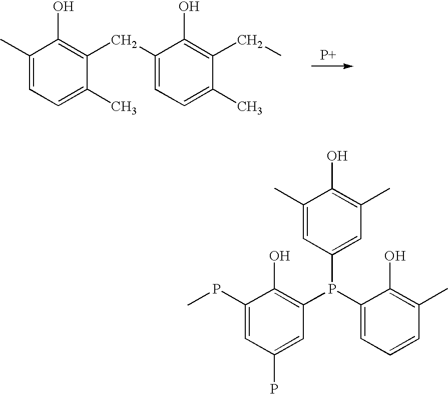

Referring to FIGS. 1A and 1B, after the ion implantation process is performed, plasma at a sufficiently high temperature is often used in a subsequent photoresist stripping process to remove the photoresist layer 10, such that the photoresist layer 10 is ashed. A temperature at which the plasma ashing process is implemented usually exceeds a gasification temperature of the solvent in the patterned photoresist layer 10. During the process of removing the crust 14, when the crust 14 is not completely stripped to expose the soft photoresist layer 12 covered thereby, a pressure underneath the crust 14 may be gradually raised with the increase in the temperature. As the temperature exceeds the gasification temperature of the solvent, the crust 14 is popped, for there is no room for the evaporated solvent within the crust 14 to escape. Sputtered photoresist fragments 10a of the photoresist layer are then tenaciously attached to the substrate 8 and to the machine. Thereby, the irremovable photoresist fragments 10a may result in contamination of the machine or yield loss of the substrate 8.

### SUMMARY OF THE INVENTION

The present invention provides a method of effectively removing a photoresist layer so as to avoid contamination of machinery or yield loss due to a popping defect of the photoresist layer.

The present invention provides a method of fabricating a semiconductor device so as to effectively remove a photoresist layer and to avoid contamination of machinery or yield loss due to a popping defect of the photoresist layer.

The present invention provides a method of removing a photoresist layer on which a process is performed to transform a surface of the photoresist layer to a crust. The crust covers a soft photoresist layer. Said method includes performing a first removing step and a second removing step. The first removing step denotes a removal of the crust so as to expose the soft photoresist layer, while the second removing step refers to a removal of the soft photoresist layer. The first and the second removing steps are performed in different chambers, and a temperature for performing the first removing step is lower than that for performing the second removing step and lower than a gasification temperature of a solvent in the soft photoresist layer.

According to one embodiment of the present invention, the temperature for performing the first removing step is lower than a gasification temperature of a solvent in the soft photoresist layer.

According to one embodiment of the present invention, the process is an ion implantation process.

According to one embodiment of the present invention, a dry stripping process is adopted in both the first removing step and the second removing step.

According to one embodiment of the present invention, the dry stripping process includes a plasma stripping process.

According to one embodiment of the present invention, the plasma stripping process adopted in the first removing step is performed in a pinning-down manner.

According to one embodiment of the present invention, the temperature at which the dry stripping process adopted in the first removing step is performed ranges from about 30° C. to 100° C.

According to another embodiment of the present invention, a wet stripping process is adopted in both the first removing step and the second removing step.

According to another embodiment of the present invention, the temperature at which the wet stripping process adopted in the first removing step is performed ranges from about 50° C. to 140° C.

According to still another embodiment of the present invention, a dry stripping process is adopted in one of the first and the second removing steps, and a wet stripping process is adopted in the other.

According to still another embodiment of the present invention, the dry stripping process includes a plasma stripping process.

According to still another embodiment of the present invention, the plasma stripping process adopted in the first removing step is performed in a pinning-down manner.

According to still another embodiment of the present invention, the dry stripping process is adopted in the first removing step and the temperature at which the dry stripping process is performed ranges from about 30° C. to 100° C.

According to still another embodiment of the present invention, the wet stripping process is adopted in the first removing step and the temperature at which the wet stripping process is performed ranges from about 50° C. to 140° C.

According to still another embodiment of the present invention, the process includes an ion implantation process.

The invention provides a method of fabricating a semiconductor device. The method includes forming a photoresist material layer on a substrate and patterning the photoresist material layer to form a first patterned photoresist layer and a second patterned photoresist layer. An area occupied by the first patterned photoresist layer is smaller than that occupied by the second patterned photoresist layer. Next, the first patterned photoresist layer and the second patterned photoresist layer are used as masks to perform an ion implantation process, such that a doped region is formed in the substrate. Here, a first crust is completely formed by the first patterned photoresist layer. A second crust is formed on a surface of the second patterned photoresist layer and a soft photoresist layer remains underlying the second crust. Thereafter, a first removing step is performed to remove the first crust and the second crust, such that the soft photoresist layer is exposed. Afterwards, a second removing step is performed to remove the soft photoresist layer. The first and the second removing steps are performed in different chambers, and a temperature for performing the first removing step is lower than that for performing the second removing step and lower than a gasification temperature of a solvent in the soft photoresist layer.

According to one embodiment of the present invention, the temperature for performing the first removing step is lower than a gasification temperature of a solvent in the soft photoresist layer.

According to one embodiment of the present invention, a dry stripping process is adopted in both the first removing step and the second removing step.

According to one embodiment of the present invention, the dry stripping process includes a plasma stripping process.

According to one embodiment of the present invention, the plasma stripping process adopted in the first removing step is performed in a pinning-down manner.

According to one embodiment of the present invention, the temperature at which the dry stripping process adopted in the first removing step is performed ranges from about 30° C. to 100° C.

According to another embodiment of the present invention, a wet stripping process is adopted in both the first removing step and the second removing step.

According to another embodiment of the present invention, the temperature at which the wet stripping process adopted in the first removing step is performed ranges from about 50° C. to 140° C.

According to still another embodiment of the present invention, a dry stripping process is adopted in one of the first and the second removing steps, and a wet stripping process is adopted in the other.

According to still another embodiment of the present invention, the dry stripping process includes a plasma stripping process.

According to still another embodiment of the present invention, the plasma stripping process adopted in the first removing step is performed in a pinning-down manner.

According to still another embodiment of the present invention, the dry stripping process is adopted in the first removing step and the temperature at which the dry stripping process is performed ranges from about 30° C. to 100° C.

According to still another embodiment of the present invention, the wet stripping process is adopted in the first removing step and the temperature at which the wet stripping process is performed ranges from about 50° C. to 140° C.

According to still another embodiment of the present invention, the first patterned photoresist layer covers an active region of the substrate.

The method of removing the photoresist layer disclosed in the present invention is capable of preventing contamination of machinery or yield loss of the substrate due to the popping defect of the photoresist layer.

The method of fabricating the semiconductor device disclosed in the present invention is able to effectively remove the photoresist layer and to avoid contamination of machinery or yield loss due to the popping defect of the photoresist layer.

In order to the make the aforementioned and other objects, features and advantages of the present invention comprehensible, a preferred embodiment accompanied with figures are described in detail below.

### BRIEF DESCRIPTION OF THE DRAWINGS

FIG. 1A is a schematic view depicting a photoresist layer on which an ion implantation process is performed according to the related art.

FIG. 1B is a schematic view depicting a popping defect of a photoresist layer during a process of removing the photoresist layer according to the related art.

FIG. 2 is a flow chart depicting a process of removing a photoresist layer according to one embodiment of the present invention.

FIGS. 3A through 3E are cross-sectional views schematically depicting a method of fabricating a semiconductor device according to one embodiment of the present invention.

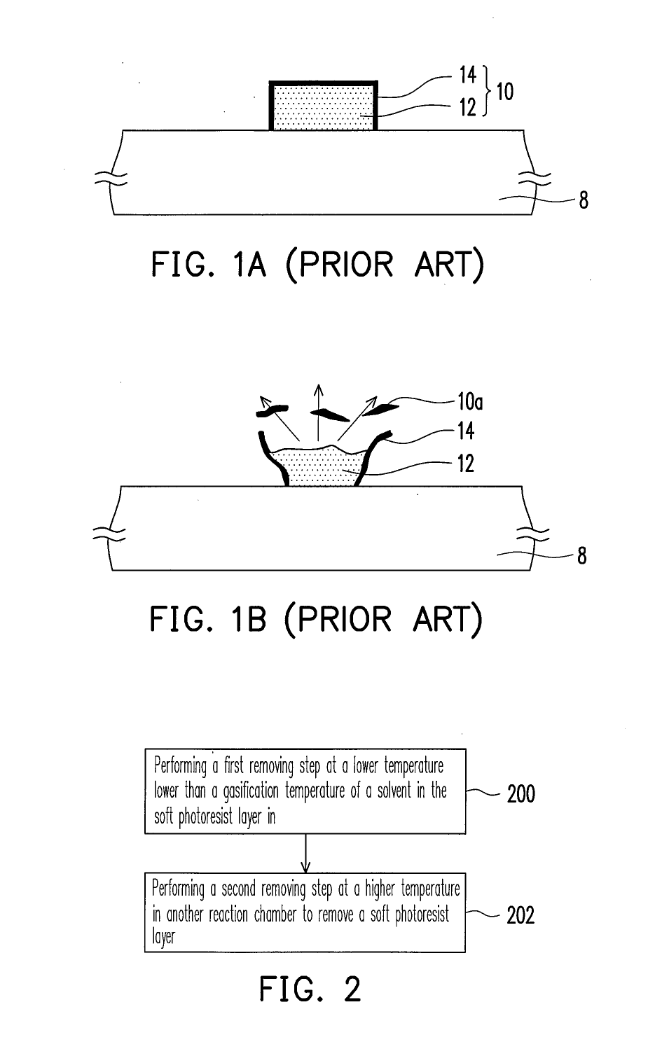

### DESCRIPTION OF EMBODIMENTS

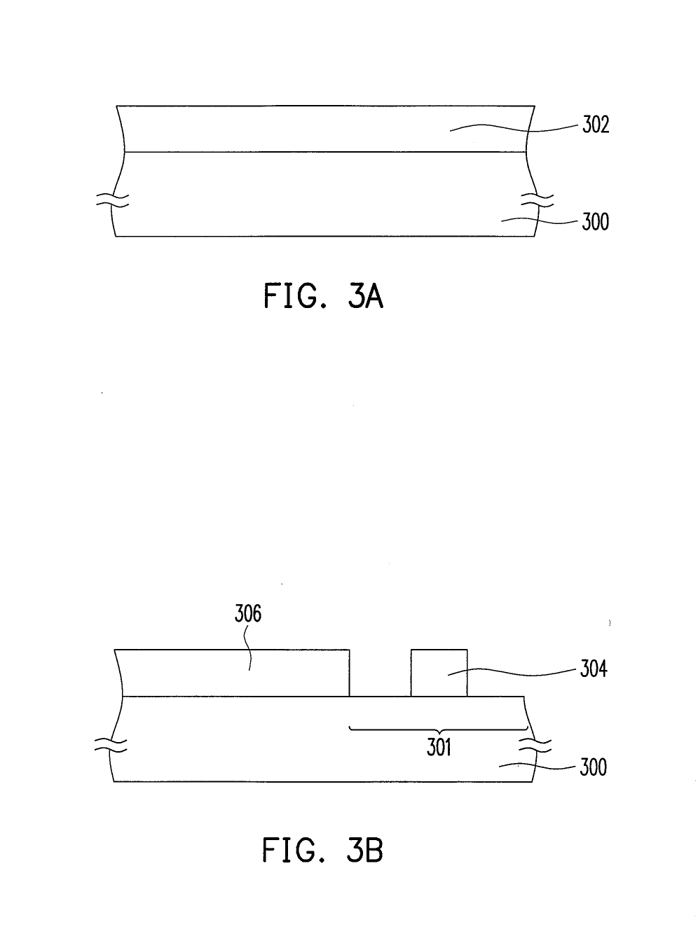

FIG. 2 is a flow chart depicting a process of removing a photoresist layer according to one embodiment of the present invention. The method of removing the photoresist layer disclosed in the present invention may be applied to the photoresist layer on which a process is performed. The photoresist material includes photosensitive polymers, resin, and solvents. After said process is carried out, a cross-linking effect is then induced on a surface of the photoresist layer, which may result from a change from an H—C—H bond to a C—C—C bond or from the following reaction,

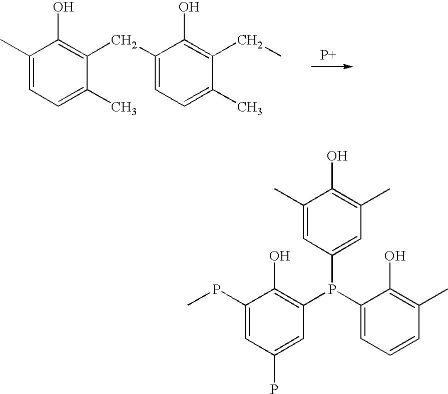

such that a crust covering a soft photoresist layer is formed on the surface of the photoresist layer. The process performed by using the solvent is, for example, an ion implantation process. The implanted ions are, for example, phosphorus, nitrogen, arsenic, antimony, carbon, germanium, boron, gallium, indium ions, and so forth.

In step 200, a first removing step is performed to strip the crust on the surface of the photoresist layer, such that the soft photoresist layer is exposed. A dry stripping process or a wet stripping process may be adopted in the first removing step. A temperature at which the dry stripping process is performed is lower than a gasification temperature of the solvent in the soft photoresist layer. In one embodiment, the temperature at which the dry stripping process is carried out ranges from about 30° C. to 100° C., for example. The dry stripping process is, for example, a plasma stripping process, which may be implemented in a machine having a single reaction chamber or a plurality of the reaction chambers. Gases adopted in said process are, for example, oxygen/hydrogen/nitrogen or oxygen/nitrogen. A pressure thereof, for example, should be more than 1.5 torr, preferably more than 5 torr. In one embodiment, said process is performed in a pinning-down manner, such that a predetermined temperature is closer to an actual temperature of the substrate. The temperature at which the wet stripping process is performed ranges from about 50° C. to 140° C. In one embodiment, the wet stripping process is performed in a chemical tank containing an organic solution or an inorganic solution. The organic solution may result in a structural damage to the photoresist so as to dissolve the same in the organic solution. The typical organic solution is, for example, acetone or aromatic solvents. On the contrary, the inorganic solution operates in a different way to remove the photoresist layer. Since the photoresist combining carbon, hydrogen and the like is organic, the inorganic solution is capable of dissolving the photoresist. The inorganic solution is, for example, sulfuric acid or hydrogen peroxide.

Next, in step 202, a second removing step is performed to remove the soft photoresist layer. The dry stripping process or the wet stripping process may be adopted in the second removing step which is performed at a higher temperature than the first removing step 200 and in a different reaction chamber from the one used in the first removing step 200. Here, the reaction chamber may refer to the reaction chamber in which the dry stripping process is performed or to the chemical tank in which the wet stripping process is carried out. In one embodiment, the second removing step 202 is a dry stripping process, and a temperature at which the dry stripping process is carried out is more than 200° C. The dry stripping process is, for example, a plasma stripping process, which may be implemented in a single reaction chamber or a machine having a plurality of the reaction chambers. Gases adopted in said process are, for example, oxygen/hydrogen/nitrogen or oxygen/nitrogen. A pressure thereof, for example, should be more than 1.5 torr, preferably more than 5 torr. In one embodiment, the wet stripping process is performed in a chemical tank containing an organic solution or an inorganic solution. The typical organic solution is, for example, acetone or aromatic solvents. The typical inorganic solution is, for example, sulfuric acid or hydrogen peroxide.

In one embodiment, a dry stripping process may be adopted in both the first removing step 200 and the second removing step 202. For example, an in-situ plasma stripping process is implemented in different reaction chambers of the same machine or an ex-situ plasma stripping process is carried out in the different reaction chambers of different machines in similar or dissimilar types or configurations. Gases adopted in said process are, for example, oxygen/hydrogen/nitrogen or oxygen/nitrogen. The first removing step is performed in a pinning-down manner. A temperature at which the first removing step 200 is implemented is lower than both the temperature at which the second removing step 202 is carried out and a gasification temperature of the solvent in the soft photoresist layer.

In another embodiment, a wet stripping process may be adopted in both the first removing step 200 and the second removing step 202. For example, the process of removing the photoresist layer is performed in different chemical tanks containing similar or dissimilar chemicals. The chemicals in the chemical tanks are, for example, the organic solution or the inorganic solution. The typical organic solution is, for example, acetone or aromatic solvents. The typical inorganic solution is, for example, sulfuric acid or hydrogen peroxide. A temperature at which the first removing step 200 is implemented is lower than both the temperature at which the second removing step 202 is carried out and a gasification temperature of the solvent in the soft photoresist layer.

In still another embodiment, a dry stripping process e.g. a plasma stripping process is adopted in the first removing step 200. Gases adopted in said process are, for example, oxygen/hydrogen/nitrogen or oxygen/nitrogen, and the first removing step 200 is performed in a pinning-down manner to remove the crust. On the other hand, a wet stripping process including stripping the soft photoresist layer in a chemical tank having chemicals may be adopted in the second removing step 202. Said wet stripping process is performed in the chemical tank containing an organic solution or an inorganic solution. The typical organic solution is, for example, acetone or aromatic solvents. The typical inorganic solution is, for example, sulfuric acid or hydrogen peroxide. A temperature at which the first removing step 200 is implemented is lower than both the temperature at which the second removing step 202 is carried out and a gasification temperature of the solvent in the soft photoresist layer.

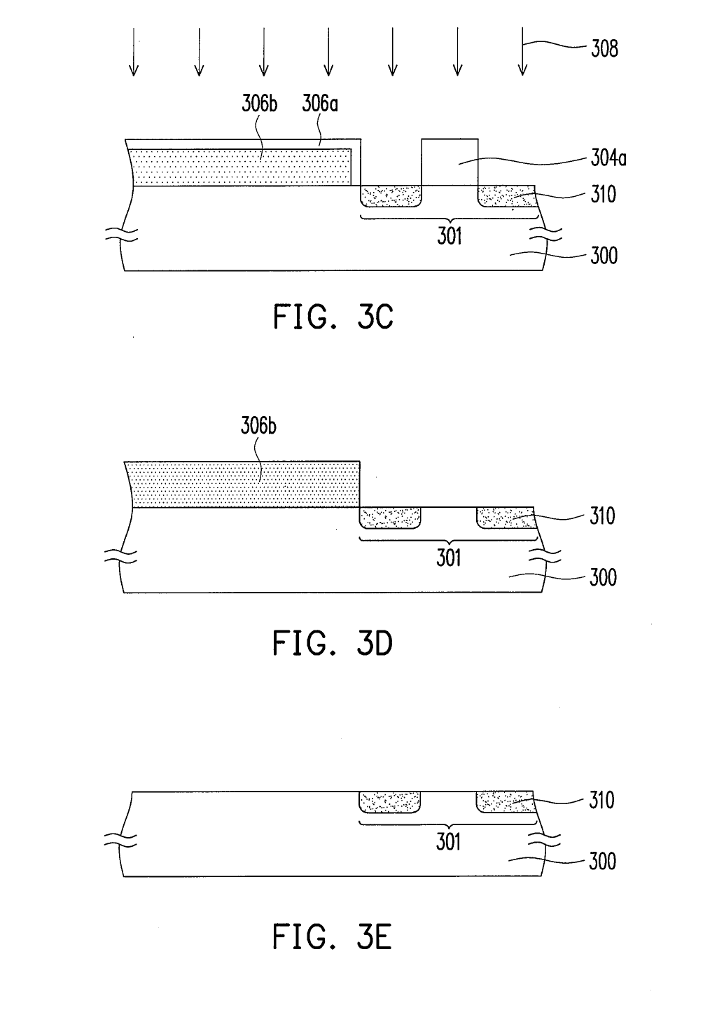

FIGS. 3A through 3E are cross-sectional views schematically depicting a method of fabricating a semiconductor device according to one embodiment of the present invention.

Referring to FIG. 3A, a photoresist material layer 302 is formed on a substrate 300. The substrate 300 is, for example, a semiconductor substrate such as a silicon substrate. Then, the photoresist material layer 302 is formed on the substrate 300. The material of the photoresist material layer 302 includes photosensitive polymers, resin, and solvents.

Next, referring to FIG. 3B, an exposure process and a development process are carried out to transform the photoresist material layer 302 to patterned photoresist layers 304 and 306. An area occupied by the patterned photoresist layer 304 is smaller than that occupied by the patterned photoresist layer 306. The patterned photoresist layer 304 covers an active region 301 of the substrate 300, for example.

Thereafter, referring to FIG. 3C, the patterned photoresist layers 304 and 306 are used as masks to perform an ion implantation process 308, such that a doped region 310 is formed in the substrate 300. The implanted ions are, for example, phosphorus nitrogen, arsenic, antimony, carbon, germanium, boron, gallium, indium ions, and so forth. The doped region 310 is, for example, a source/drain extension region, a source/drain, a diode doped region, a well, a field implanted region, a pocket ion implanted region, lightly doped drain (LDD) region and so forth. After the ion implantation process 308 is implemented, the smaller patterned photoresist layer 304 is completely transformed into a crust 304a, while only a surface of the larger patterned photoresist layer 306 is transformed into a crust 306a, and a soft photoresist layer 306b remains therein.

Afterwards, referring to FIG. 3D, a first removing step is performed to remove the crusts 304a and 306a according to said embodiment, such that the soft photoresist layer 306b is exposed.

Then, referring to FIG. 3E, a second removing step is performed to remove the soft photoresist layer 306b according to said embodiment. The second removing step is performed at a higher temperature than the first removing step and in a different reaction chamber from the one used in the first removing step. The reaction chamber may refer to the reaction chamber in which a dry stripping process is performed or to a chemical tank in which a wet stripping process is carried out.

With lower temperature, lower than 100° C., for example, the first removing step of the present invention prevents contamination of machinery or yield loss due to a popping defect of the photoresist layer. The popping defect is caused by evaporation of the solvent in the photoresist layer. On the contrary, the second removing step is performed at a higher temperature, and thus the residual soft photoresist layer is effectively stripped. In comparison with a process of removing the photoresist layer with use of a high-temperature RCA, the stripping process of the photoresist layer disclosed in the present invention prevents a significant loss of an oxide layer due to the use of the high-temperature RCA.

Moreover, in comparison with a process of removing the photoresist layer with use of a low-temperature RCA, the stripping process of the photoresist layer disclosed in the present invention avoids incomplete removal of the photoresist layer on account of the use of the low-temperature RCA. In addition, since the first and the second removing steps are implemented in different reaction chambers, contamination caused by the popping defect of the photoresist layer can be avoided, and the throughput can also be increased.

### EXPERIMENT

### Example 1

A substrate is provided. A patterned photoresist layer is already formed on the substrate, and an ion implantation process is already performed thereon. Next, a first removing step is performed in a first chamber of a plasma machine in a pinning-down manner. A temperature at which the first removing step is performed is 90° C. Gases adopted in said step is O₂ and N₂H₂. A pressure thereof is 5 torr. Thereafter, a second removing step is performed in a different chamber of the same plasma machine The temperature at which the second removing step is performed is 250° C. The gases adopted in said step is O₂ and N₂H₂. The pressure thereof is 5 torr. Afterwards, defects on the substrate are measured. Finally, a cleaning process is performed, and the defects on the substrate are again measured. The test results are shown in table 1. Comparative Example 1 is performed using the prior art method.

TABLE 1

| | | | | Comparative | |
|---|---|---|---|---|---|
| | Example 1 | | | Example 1 | |
| | Sample 1 | Sample 2 | Sample 3 | Sample 1 | Sample 2 |
| Post strip | 23 | 65 | 23 | 10101 | 8757 |
| defect | | | | | |
| Post clean | 14 | 18 | 21 | 181 | 124 |
| defect | | | | | |

It is understood from table 1 that the present invention can significantly reduce the defects arisen from the popping defect of the photoresist layer and further raise yield of the fabricating process.

Although the present invention has been disclosed above by the preferred embodiments, they are not intended to limit the present invention. Anybody skilled in the art can make some modifications and alteration without departing from the spirit and scope of the present invention. Therefore, the protecting range of the present invention falls in the appended claims.

1. A method of removing a photoresist layer on which a process is performed to transform a surface of the photoresist layer to a crust, the crust covering a soft photoresist layer, the method comprising:
performing a first removing step with a mixing gas of H₂/O₂/N₂ to remove the crust, such that the soft photoresist layer is exposed, wherein the temperature of the first removing step is performed ranges from about 30° C. to 100° C.; and
performing a second removing step to remove the soft photoresist layer,
wherein the first and the second removing steps are performed in different chambers, and a temperature for performing the first removing step is lower than that for performing the second removing step and lower than a gasification temperature of a solvent in the soft photoresist layer.

2. The method of claim 1, wherein the process is an ion implantation process.

3. The method of claim 1, wherein a dry stripping process is adopted in both the first removing step and the second removing step.

4. The method of claim 3, wherein the dry stripping process comprises a plasma stripping process.

5. The method of claim 4, wherein the plasma stripping process adopted in the first removing step is performed in a pinning-down manner.

6-8. (canceled)

9. The method of claim 1, wherein a dry stripping process is adopted in the first removing step, and a wet stripping process is adopted in the second removing step.

10. The method of claim 9, wherein the dry stripping process comprises a plasma stripping process.

11. The method of claim 10, wherein the plasma stripping process adopted in the first removing step is performed in a pinning-down manner.

12. (canceled)

13. The method of claim 9, wherein the temperature at which the wet stripping process is performed ranges from about 50° C. to 140° C.

14. (canceled)

15. A method of fabricating a semiconductor device, comprising:
forming a photoresist material layer on a substrate;
patterning the photoresist material layer to form a first patterned photoresist layer and a second patterned photoresist layer, an area occupied by the first patterned photoresist layer being smaller than that occupied by the second patterned photoresist layer;
performing an ion implantation process to form a doped region in the substrate with use of the first patterned photoresist layer and the second patterned photoresist layer as masks, a first crust being completely formed by the first patterned photoresist layer, a second crust being formed on a surface of the second patterned photoresist layer and a soft photoresist layer being formed underlying the second crust;
performing a first removing step with a mixing gas of H₂/O₂/N₂ to remove the first crust and the second crust, such that the soft photoresist layer is exposed, wherein the temperature of the first removing step is performed ranges from about 30° C. to 100° C.; and
performing a second removing step to remove the soft photoresist layer,
wherein the first and the second removing steps are performed in different chambers, and a temperature for performing the first removing step is lower than that for performing the second removing step and lower than a gasification temperature of a solvent in the soft photoresist layer.

16. The method of claim 15, wherein a dry stripping process is adopted in both the first removing step and the second removing step.

17. The method of claim 16, wherein the dry stripping process comprises a plasma stripping process.

18. The method of claim 17, wherein the plasma stripping process adopted in the first removing step is performed in a pinning-down manner.

19-21. (canceled)

22. The method of claim 15, wherein a dry stripping process is adopted in the first removing step, and a wet stripping process is adopted in the second removing step.

23. The method of claim 22, wherein the dry stripping process comprises a plasma stripping process.

24. The method of claim 23, wherein the plasma stripping process adopted in the first removing step is performed in a pinning-down manner.

25. (canceled)

26. the method of claim 22, wherein the temperature at which the wet stripping process is performed ranges from about 50° C. to 140° C.

17. The method of claim 15, wherein the first patterned photoresist layer covers an active region of the substrate.
